(19) United States
(12) Patent Application Publication
(10) Pub. No.: US 2026/0282609 A1
(43) Pub. Date: Sep. 17, 2026

(54) LIGHT EMITTING MODULE

(71) Applicant: Seoul Viosys Co., Ltd., Ansan-si (KR)

(72) Inventor: Chunghoon LEE, Ansan-si (KR)

(73) Assignee: Seoul Viosys Co., Ltd., Ansan-si (KR)

(21) Appl. No.: 19/564,816

(22) Filed: Mar. 12, 2026

Related U.S. Application Data
(60) Provisional application No. 63/771,889, filed on Mar. 14, 2025.

(51) Int. Cl. H10H 20/821; H10H 20/853; H10H 29/14

(52) U.S. Cl. CPC H10H 20/821; H10H 20/853; H10H 29/14

(57) ABSTRACT

The present invention discloses a light emitting module including a support layer, a light emitting device disposed on the support layer, and a light-transmitting layer disposed on an upper surface of the light emitting device, in which a point where an absolute value of a tangent slope of a light exiting surface of the light-transmitting layer is 1 is positioned between an upper-lower center line of the light-transmitting layer and an upper end of the light-transmitting layer.

### CROSS-REFERENCE TO RELATED APPLICATIONS

This application claims the benefit of U.S. Provisional Patent Application No. 63/771,889, filed on Mar. 14, 2025, the content of which is hereby incorporated by reference for all purposes as if fully set forth herein.

### TECHNICAL FIELD

The present invention relates to a light emitting module including a light emitting device.

### BACKGROUND

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, it has been rapidly replacing a conventional light source. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current may flow from the p-electrode pad through the semiconductor layers to the n-electrode pad, and light generated through recombination of electrons and holes in the active layer may be emitted.

### TECHNICAL PROBLEM

The present invention aims to provide a light emitting module with improved light emitting performance and reliability.

The present invention aims to provide a light emitting module that is configured to simplify a manufacturing process and improve mass productivity.

The present invention aims to provide a light emitting module having high light collimation efficiency, light uniformity and light directivity by effectively collimating light emitted from a light emitting device to increase straightness and minimize loss along an optical path.

The present invention aims to provide a light emitting module that is configured to ultimately provide output light having a uniform and symmetrical light distribution by correcting a non-uniform light emitting characteristic inherent in a light emitting device.

The present invention aims to provide a light emitting module with improved durability and reliability by effectively protecting a light emitting device from an external environment and increasing structural stability.

### TECHNICAL SOLUTION

An embodiment of the present invention discloses a light emitting module including a support layer, a light emitting device disposed on the support layer, and a light-transmitting layer disposed on an upper surface of the light emitting device.

In an embodiment, a point where an absolute value of a tangent slope of a light exiting surface of the light-transmitting layer is 1 may be positioned between an upper-lower center line of the light-transmitting layer and an upper end of the light-transmitting layer.

In an embodiment, a vertical center axis of the light-transmitting layer may be spaced apart from a vertical center axis of the light emitting device.

In an embodiment, a vertical length from the upper surface of the light emitting device to the upper end of the light-transmitting layer may be longer than a vertical length of the light emitting device.

In an embodiment, the light emitting module includes a plurality of light emitting devices disposed on the support layer, and the light-transmitting layer may be provided in a plurality corresponding to the plurality of light emitting devices.

In an embodiment, a center-to-center distance between two adjacent light-transmitting layers may be longer than a width of the light emitting device.

In an embodiment, a separation distance between two adjacent light-transmitting layers may be shorter than a separation distance between two adjacent light emitting devices.

In an embodiment, the separation distance between two adjacent light-transmitting layers may be shorter than the width of the light emitting device.

In an embodiment, the separation distance between two adjacent light emitting devices may be longer than the width of the light emitting device.

In an embodiment, the light emitting module may further include a connection layer connecting two adjacent light-transmitting layers.

In an embodiment, a concave groove may be formed at a lower portion of the connection layer.

In an embodiment, the light emitting module includes a plurality of light emitting devices disposed on the support layer, and the plurality of light emitting devices may share the light-transmitting layer.

In an embodiment, the light exiting surface of the light-transmitting layer may be a convex surface.

In an embodiment, the light exiting surface of the light-transmitting layer may further include a vertical surface on a side surface.

In an embodiment, the light exiting surface of the light-transmitting layer may have a modified region formed on the side surface.

Another embodiment of the present invention discloses a light emitting module including a support layer, a light emitting device disposed on the support layer, and a light-transmitting layer disposed on an upper surface of the light emitting device, in which a light exiting surface of the light-transmitting layer includes an inclined surface having a slope, and the inclined surface is positioned between an upper-lower center line of the light-transmitting layer and an upper end of the light-transmitting layer.

In an embodiment, an upper surface of the light exiting surface may be a flat surface.

In an embodiment, the light emitting module may further include a molding layer disposed on a side surface of the light emitting device.

In an embodiment, the light emitting module includes a plurality of light emitting devices disposed on the support layer, and the plurality of light emitting devices may share the light-transmitting layer.

Another embodiment of the present invention discloses a light emitting module including a support layer, a light emitting device disposed on the support layer, and a light-transmitting layer disposed on an upper surface of the light emitting device, in which a light exiting surface of the light-transmitting layer includes an inclined surface having a slope, and the inclined surface is positioned between an upper-lower center line of the light-transmitting layer and a lower end of the light-transmitting layer.

In an embodiment, the light emitting module further includes a molding layer disposed on a side surface of the light emitting device, and a maximum width of the light-transmitting layer may be wider than a maximum width of the molding layer.

### ADVANTAGEOUS EFFECT

The present invention may provide a light emitting module with improved light emitting performance and reliability.

The present invention may provide a light emitting module that is configured to simplify a manufacturing process and improve mass productivity.

The present invention may provide a light emitting module having high light collimation efficiency, light uniformity and light directivity by effectively collimating light emitted from a light emitting device to increase straightness and minimize loss along an optical path.

The present invention may provide a light emitting module that is configured to ultimately provide output light having a uniform and symmetrical light distribution by correcting a non-uniform light emitting characteristic inherent in a light emitting device.

The present invention may provide a light emitting module with improved durability and reliability by effectively protecting a light emitting device from an external environment and increasing structural stability.

### BRIEF DESCRIPTION OF THE DRAWINGS

FIG. 1 is a cross-sectional view showing a light emitting module according to a first embodiment of the present invention.

FIG. 2 is a cross-sectional view showing a light emitting module according to a second embodiment of the present invention.

FIG. 3 is a cross-sectional view showing a light emitting module according to a third embodiment of the present invention.

FIG. 4 is a cross-sectional view showing a light emitting module according to a fourth embodiment of the present invention.

FIG. 5 is a cross-sectional view showing a light emitting module according to a fifth embodiment of the present invention.

FIG. 6 is a cross-sectional view showing a light emitting module according to a sixth embodiment of the present invention.

FIG. 7 is a cross-sectional view showing a light emitting module according to a seventh embodiment of the present invention.

FIG. 8 is a cross-sectional view showing a light emitting module according to an eighth embodiment of the present invention.

FIG. 9 is a cross-sectional view showing a light emitting module according to a ninth embodiment of the present invention.

FIG. 10 is a cross-sectional view showing a light emitting module according to a tenth embodiment of the present invention.

FIG. 11 is a cross-sectional view showing a light emitting module according to an 11th embodiment of the present invention.

FIG. 12 is a cross-sectional view showing a light emitting module according to a 12th embodiment of the present invention.

FIG. 13 is a side view showing an example of a light emitting system including a light emitting module according to an embodiment of the present invention.

FIG. 14 is a side view showing another example of a light emitting system including a light emitting module according to an embodiment of the present invention.

FIG. 15 is a side view showing another example of a light emitting system including a light emitting module according to an embodiment of the present invention.

FIG. 16 is a side view showing another example of a light emitting system including a light emitting module according to an embodiment of the present invention.

FIG. 17 is a conceptual diagram showing another example of a light emitting system including a light emitting module according to an embodiment of the present invention.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting module of the present invention will be described in detail through accompanying drawings.

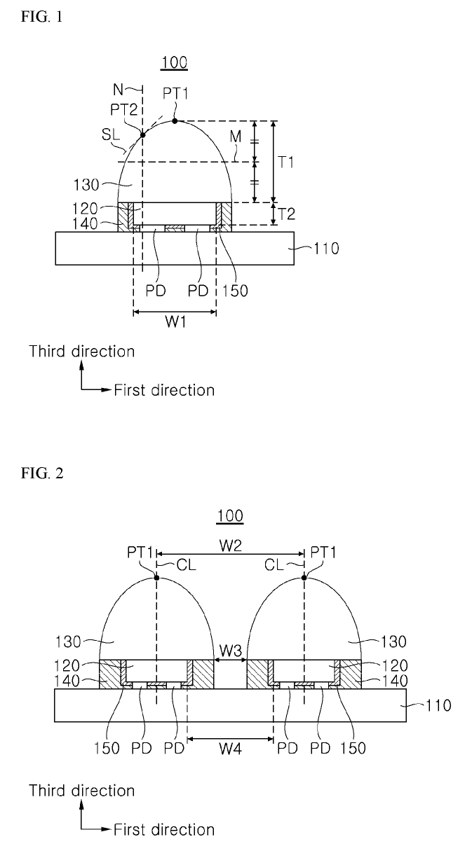

FIG. 1 is a cross-sectional view illustrating a light emitting module 100 according to a first embodiment of the present invention, and a first direction illustrated in FIG. 1 may represent a lateral direction, and a third direction may represent a vertical direction.

The light emitting module 100 may include a support layer 110, a light emitting device 120 disposed on the support layer 110, and a light-transmitting layer 130 disposed on an upper surface of the light emitting device 120.

The support layer 110 is a substrate that supports an overall structure of the light emitting module 100, and the light emitting device 120 may be mounted on its upper surface. For example, the support layer 110 may be formed of various materials such as a silicon substrate, a printed circuit board (PCB), a ceramic substrate, or the like, and may have a circuit pattern (not shown in the drawings) for driving the light emitting device 120.

In detail, a circuit electrode electrically connected to an electrode pad PD of the light emitting device 120 may be formed on the upper surface of the support layer 110, and a wiring pattern connected to the circuit electrode may be provided therein. In addition, the support layer 110 may include a controller or driver IC that controls a turn-on/off, brightness, color, or others of the light emitting device 120, or may be connected to an external driver. The support layer 110 may be implemented as a printed circuit board (PCB)of FR-4 material, a flexible polyimide (PI) substrate, a ceramic substrate with favorable heat dissipation characteristics, or the like.

The light emitting device 120 may be a light emitting diode mounted on the support layer 110 and emitting light of a specific wavelength band when power is applied. In an embodiment, the light emitting device 120 may be a micro light emitting diode (micro-LED).

The light emitting device 120 may have a width W1 in the first direction, and a vertical length T2 in the third direction. The width W1 may have a size of, for example, 100 µm or less, or 50 µm or less.

A plurality of electrode pads PD may be formed on a lower surface of the light emitting device 120 so as to be electrically connected to the support layer 110. The light emitting device 120 may receive driving power through the electrode pads PD to emit light.

The light emitting device 120 may include, for example, a first conductivity type semiconductor layer doped with a first conductivity type dopant, a second conductivity type semiconductor layer doped with a second conductivity type dopant, and an active layer disposed between the first conductivity type semiconductor layer and the second conductivity type semiconductor layer.

The first conductivity type semiconductor layer may include a phosphide or nitride semiconductor such as (Al, Ga, In)P or (Al, Ga, In)N. In addition, the first conductivity type semiconductor layer may be doped as an n-type by including one or more impurities such as Si, C, Ge, Sn, Te, Pb, or others. The present invention is not limited thereto, and as another example, the first conductivity type semiconductor layer may be doped with an opposite conductivity type, including a p-type dopant. In addition, the first conductivity type semiconductor layer may be formed as a single layer or multiple layers.

The second conductivity type semiconductor layer may include a phosphide or nitride semiconductor such as (Al, Ga, In)P or (Al, Ga, In)N. The second conductivity type semiconductor layer may be doped with a conductivity type opposite to that of the first conductivity type semiconductor layer. For example, the second conductivity type semiconductor layer may be doped as a p-type by including an impurity such as Mg.

The active layer is a light emitting layer disposed between the first conductivity type semiconductor layer and the second conductivity type semiconductor layer, may include a phosphide or nitride semiconductor such as (Al, Ga, In)P or (Al, Ga, In)N, and may be grown on the first conductivity type semiconductor layer using a technique such as MOCVD, MBE, HVPE, or the like.

In addition, the active layer may include a quantum well structure (QW) including at least two barrier layers and at least one well layer. Furthermore, the active layer may include a multi quantum well structure (MQW) including a plurality of barrier layers and a plurality of well layers. A wavelength of light emitted from the active layer may be adjusted by controlling a composition ratio of materials forming the well layer. In this case, the well layer may include a same element in common, for example, In.

A light exiting surface through which light is emitted may be formed on a side of the first conductivity type semiconductor layer or the second conductivity type semiconductor layer. For example, light generated in the active layer may be emitted to the outside through the first conductivity type semiconductor layer, or may be emitted to the outside through the second conductivity type semiconductor layer. Irregularities or projections may be formed on a surface of the first conductivity type semiconductor layer or on a surface of the second conductivity type semiconductor layer so as to increase light extraction efficiency.

The light emitting module 100 may further include an insulation layer 150 disposed on a side surface of the light emitting device 120. The insulation layer 150 may be an optional configuration.

The insulation layer 150 may protect an active region of the light emitting device 120 from an external environment and prevent an electrical short that may occur on the side surface.

In addition, the light emitting module 100 may further include a molding layer 140 disposed on the side surface of the light emitting device 120. The molding layer 140 may physically secure the light emitting device 120 and protect it from moisture or external impact, thereby improving an overall reliability of the light emitting module 100. The molding layer 140 may be an optional configuration.

The molding layer 140 is formed on the support layer 110, and may wrap the light emitting device 120 and an outer side of the insulation layer 150 surrounding it.

The molding layer 140 may protect a fragile micro light emitting device 120 from external physical shock or vibration, and block external environmental factors such as moisture or oxygen from infiltrating into the active region of the device, thereby securing long-term reliability and durability of the light emitting module 100. To this end, the molding layer 140 may be formed of a polymer resin material with favorable adhesiveness and insulation and low moisture permeability, such as epoxy molding compound (EMC) or silicone.

In addition, the molding layer 140 may also perform an optical function. For example, the molding layer 140 may be formed of a material including a black pigment or carbon black that absorbs light. This may effectively absorb stray light leaking to the side surface of the light emitting device 120 and prevent optical crosstalk between adjacent light emitting devices 120. In addition, when applied to a display, it is possible to significantly improve a contrast ratio by suppressing external light reflection.

The light-transmitting layer 130 may be disposed on the upper surface of the light emitting device 120. The light-transmitting layer 130 may form an optical path through which light emitted from the light emitting device 120 is emitted to the outside. The light-transmitting layer 130 may perform a role as a lens depending on its shape.

The light-transmitting layer 130 may have a vertical length T1 in the third direction. The vertical length T1 of the light-transmitting layer 130 may mean a vertical distance from the upper surface of the light emitting device 120 to a first point PT1, which is an uppermost vertex of the light-transmitting layer 130.

The vertical length T1 affects a curvature and a focal length of the light-transmitting layer 130, and may allow light emitted from the light emitting device 120 to pass through a sufficient optical path length therein and be effectively collimated.

For example, the vertical length T1 may be formed to be longer than the vertical length T2 of the light emitting device 120, thereby securing a sufficient volume for the light-transmitting layer 130 to control light. Meanwhile, a center line M which will be described later may be an imaginary lateral reference line that bisects the vertical length T1 in the vertical direction.

A surface of the light-transmitting layer 130, that is, the light exiting surface, may have a convex curved shape. The curved structure may effectively refract light emitted from the light emitting device 120 at a wide angle, thereby making light collimated close to a center. Accordingly, a luminance intensity in a front direction of the light emitting module 100 may be increased and a divergence angle of a beam may be reduced, thereby improving an optical performance, such as increased optical coupling efficiency in an optical communication system or improved brightness of a display.

In addition, a second point PT2 where an absolute value of a slope of a tangent line SL of the light exiting surface of the light-transmitting layer 130 is 1 may be positioned between an upper-lower center line M of the light-transmitting layer 130 and an upper end of the light-transmitting layer 130.

In detail, in FIG. 1, the second point PT2 of the light exiting surface may represent a point where the absolute value of the slope of the tangent line SL with respect to the first direction becomes 1, that is, a point where the tangent line forms a 45° angle with a lateral axis. When a peak of an uppermost end of the light-transmitting layer 130 is referred to as the first point PT1, the second point PT2 may be positioned between the first point PT1 and the upper-lower center line M based on the upper-lower center line M of the light-transmitting layer 130. In other words, a vertical position of the second point PT2 may be positioned in an upper half of an entire vertical length T1 of the light-transmitting layer 130.

A vertical imaginary line N extending from the second point PT2 toward the light emitting device 120 may cross the light emitting device 120.

A vertical length from the second point PT2 to the first point PT1 may be 0.5 or less of the vertical length T1 from the upper surface of the light emitting device 120 to the first point PT1.

The larger a curvature (the steeper the slope) of the light-transmitting layer 130, the stronger the ability to refract light may be. Since the second point PT2 is positioned in the upper half of the light-transmitting layer 130, a region with a large curvature that plays a crucial role in collimating light may be concentrated at an upper end portion of the light-transmitting layer 130. Through this, a straightness of light emitted from the light emitting device 120 may be maximized and a spread of the beam may be minimized, thereby optimizing a light collimation efficiency of the light emitting module 100.

FIG. 2 is a cross-sectional view illustrating a light emitting module 100 according to a second embodiment of the present invention. The light emitting module 100 according to the second embodiment will be described in detail, focusing on differences from the first embodiment.

The light emitting module 100 may include a plurality of light emitting devices 120 disposed on the support layer 110. FIG. 2 exemplarily illustrates that the light emitting module 100 includes two light emitting devices 120, but the number of light emitting devices 120 is not limited thereto.

The support layer 110 is common to the plurality of light emitting devices 120, and the plurality of light emitting devices 120 may be spaced apart from `one another on a plane including a first direction and a second direction (a direction perpendicular to the first direction and a third direction). FIG. 2 exemplarily illustrates that the light emitting devices 120 are spaced apart in the first direction, but the present invention is not limited thereto. The plurality of light emitting devices 120 may be disposed in various patterns such as a matrix, honeycomb, or others on a surface of the common support layer 110.

Each of the light emitting devices 120 is supplied with driving power through the electrode pad PD, as in the first embodiment, and a side surface thereof may be protected by the insulation layer 150 and the molding layer 140.

The light-transmitting layer 130 may be provided in a plurality corresponding to the plurality of light emitting devices 120. A discrete light-transmitting layer 130 may be disposed on an upper surface of each of the light emitting devices 120, thereby forming a lens array that independently collimates light emitted from each of the light emitting devices 120.

In FIG. 2, W2 may be a center-to-center distance W2 between first points PT1 of two adjacent light-transmitting layers 130. The W2 may represent a pitch.

The center-to-center distance W2 may be longer than a width W1 of a single light emitting device 120. Through this, a separation distance for minimizing electrical and thermal interference may be secured.

In FIG. 2, W4 may represent a separation distance between two adjacent light emitting devices 120. The separation distance W4 may be longer than the width W1 of the light emitting device 120. Through this, sufficient space may be secured between the light emitting devices 120, and thus, errors in a manufacturing process may be absorbed and heat generated during operation may be prevented from being transferred to other light emitting devices 120, thereby increasing reliability.

In FIG. 2, W3 may represent a minimum separation distance (a separation distance at a lower end portion) between two adjacent light-transmitting layers 130. The separation distance W3 may be shorter than the width W1 of the light emitting device 120. Through this, an integration density of an entire light emitting module 100 may be maximized.

In addition, the separation distance W3 between the light-transmitting layers 130 may be shorter than the separation distance W4 between the light emitting devices 120. Through this, light emitted from one light emitting device 120 may be effectively blocked from leaking toward an adjacent light emitting device 120, thereby reducing optical crosstalk.

Meanwhile, in FIG. 2, a vertical center axis CL of the light-transmitting layer 130 may coincide with a vertical center axis of a corresponding light emitting device 120. As another example, the vertical center axis CL of the light-transmitting layer 130 may be intentionally spaced apart at a predetermined distance from the vertical center axis of the light emitting device 120. Such an axis misalignment structure may correct an asymmetrical light emission pattern inherent in the light emitting device 120. That is, by intentionally eccentricating a center of an optical system, a distribution of light finally emitted to the outside may be made more uniform and symmetrical, thereby improving an overall optical quality.

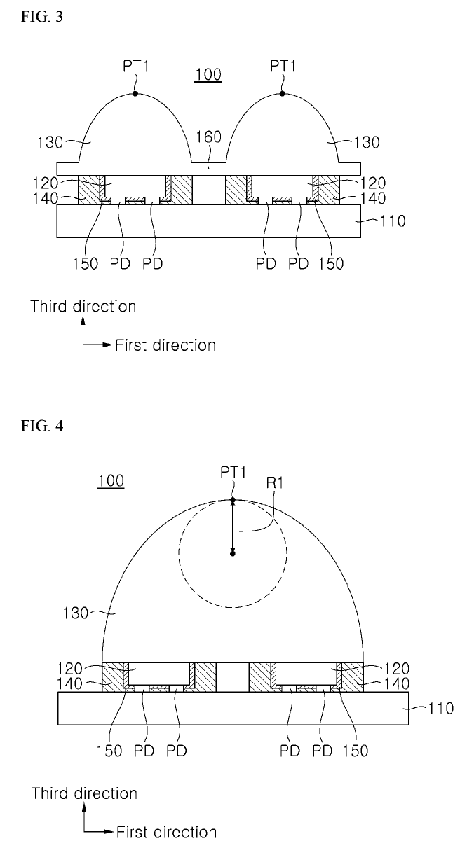

FIG. 3 is a cross-sectional view illustrating a light emitting module 100 according to a third embodiment of the present invention. The light emitting module 100 according to the third embodiment will be described in detail, focusing on differences from the first and second embodiments.

In FIG. 3, the light emitting module 100 may further include a connection layer 160 that connects two adjacent light-transmitting layers 130. In FIG. 2, a plurality of light-transmitting layers 130 that have been discretely isolated may be physically connected through the connection layer 160 to form one monolithic lens array. Through this, manufacturing processability and structural stability may be improved.

The fact that the plurality of light emitting devices 120 are spaced apart from one another on the support layer 110 is similar to the embodiment of FIG. 2. In the third embodiment, a single layer in which multiple light-transmitting layers 130 are formed integrally, rather than discrete light-transmitting layers 130, is disposed on an upper surface of each of the light emitting devices 120. In this structure, the connection layer 160 may be a base portion that physically connects two adjacent light-transmitting layers 130 at a lower portion. A thickness of the base portion may be smaller than that of the light emitting device 120. Therefore, light diffusion through the base portion may be prevented.

Through this, manufacturing processability may be improved. When the plurality of light-transmitting layers 130 are manufactured as one integrated component as in the third embodiment, a single integrated component may be arranged at a wafer level or panel level at once. This may be very advantageous for mass production as the process is simplified, arrangement accuracy is increased, and manufacturing time and cost are significantly reduced.

In addition, since all of the light-transmitting layers 130 are connected as one robust solid component, a risk of discrete light-transmitting layers 130 being warped or detached due to external shock or vibration may be reduced. This may increase a mechanical strength of the light emitting module 100, thereby improving long-term durability and reliability.

FIG. 4 is a cross-sectional view illustrating a light emitting module 100 according to a fourth embodiment of the present invention. The light emitting module 100 according to the fourth embodiment will be described in detail, focusing on differences from the first through third embodiments.

In FIG. 4, the plurality of light emitting devices 120 may share one light-transmitting layer 130. While the embodiment of FIG. 3 has an optical boundary by placing the connection layer 160 between each of the light transmitting layers 130. the fourth embodiment, without such distinction, may have a structure in which one continuous dome-shaped light-transmitting layer 130 covers the plurality of light emitting devices 120 at once.

Through thus, a simplicity of the manufacturing process may be maximized. Without a need to discretely manufacture the plurality of light-transmitting layers 130, or use a complex mold with the connection layer 160, only one dome-shaped light-transmitting layer 130 may be manufactured and disposed on an array of the plurality of light emitting devices 120 at once. This may reduce the number of components and minimize processes, thereby significantly reducing overall manufacturing costs and time.

In addition, structural robustness may be secured. Since the light-transmitting layer 130 is formed as one mass without physical disconnection or a thin connection layer 160, it may have very robust resistance to external shock or vibration. This may ensure a mechanical reliability and long-term durability of the light emitting module 100.

In addition, light emitted from the plurality of light emitting devices 120 may be allowed to mix and overlap with one another within the single light-transmitting layer 130, thereby providing uniform illumination over a wider area or forming a more powerful single light source.

A radius of curvature R1 at the first point PT1 of the light-transmitting layer 130 may be smaller than the vertical length T1 of the light-transmitting layer 130. Alternatively, the radius of curvature R1 at the first point PT1 may be greater than the vertical length T2 of the light emitting device 120.

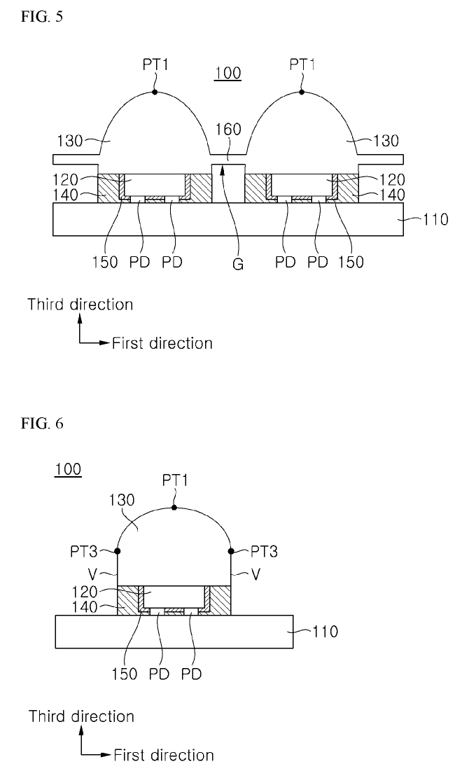

FIG. 5 is a cross-sectional view illustrating a light emitting module 100 according to a fifth embodiment of the present invention. The light emitting module 100 according to the fifth embodiment will be described in detail, focusing on differences from the first through fourth embodiments.

The fifth embodiment is based on a structure in which a plurality of light-transmitting layers 130 are integrally formed as shown in FIG. 3, but optical and mechanical characteristics may be improved through structural deformation of the connection layer 160. To this end, a concave groove G may be formed at a lower portion of the connection layer 160.

In the fifth embodiment, a fact that a plurality of light emitting devices 120 are spaced apart on the support layer 110, and the light-transmitting layer 130 formed as one single body covers entire light emitting devices is similar to that of the third embodiment. In the fifth embodiment, the concave groove G may be formed on a lower surface of the connection layer 160, that is, on a surface facing the support layer 110. The concave groove G has a shape in which a central lower portion of the connection layer 160 is dug upward (in a third direction), and as a result, a cross-section of the connection layer 160 may have a shape of an arch or an inverted 'U'.

Through this, optical isolation performance between light emitting units may be improved. As the concave groove G is formed, a physical space, that is, an air gap, may be created between the connection layer 160 and the support layer 110. When light emitted from one light emitting device 120 passes through a molding layer 140 on a side surface or is scattered on a surface of the support layer 110 to propagate into an adjacent channel, this air gap may play a role as a barrier having a large difference in refractive index, thereby effectively blocking, or scattering the propagation of light. This may suppress optical crosstalk between adjacent light emitting units, thereby ensuring signal independence of each channel and improving a signal-to-noise ratio of an entire system.

In addition, mechanical stress may be effectively dispersed through an arch-shaped structure by the groove G. When stress is concentrated on the connection layer 160 due to thermal expansion or external physical impact that occurs while the light emitting module 100 is operating, the arch structure formed by the groove G may alleviate and disperse this stress, thereby preventing damage or deformation of the connection layer and increasing an overall mechanical reliability of the light emitting module 100.

FIG. 6 is a cross-sectional view illustrating a light emitting module 100 according to a sixth embodiment of the present invention. The light emitting module 100 according to the sixth embodiment will be described in detail, focusing on differences from the first through fifth embodiments. The sixth embodiment may implement additional functions and effects by modifying the shape of the light exiting surface of the light-transmitting layer 130 of the first embodiment.

In the sixth embodiment, a light exiting surface of the light-transmitting layer 130 may not be formed of a single curved surface, but may have a composite shape. In detail, the light exiting surface may include a vertical side surface part of a lower portion, and a convex dome-shaped part of an upper portion. A boundary between the two parts may be represented by an inflection point PT3.

That is, the upper portion of the light exiting surface may have a convex surface shape. Accordingly, light emitted from the light emitting device 120 may be effectively collimated to improve straightness. A lower side surface of the light exiting surface may include a vertical surface V perpendicular to a third direction.

A modified region may be formed on the vertical surface V. The modified region may be implemented by applying a black coating layer that absorbs light, carbonizing the surface through laser processing to impart light absorption characteristics, or roughening the surface to scatter light.

Among light emitted from the light emitting device 120, stray light that travels at a high angle and goes beyond a light collimation range of a lens may be absorbed or scattered by the modified region and not be emitted to the outside. Through this, an overall beam quality of the light emitting module 100 may be improved by removing unnecessary stray light. In addition, in a case that a plurality of light emitting modules 100 are arranged, it is possible to block optical crosstalk caused by stray light passing over an adjacent channel.

The shape of the light-transmitting layer 130 illustrated in FIG. 6, that is, a height of the vertical surface or a curvature of the convex surface, is merely an example for implementing the technical idea of the present invention, and its shape may be modified in various ways depending on a required optical performance.

The sixth embodiment may effectively collimate light through the convex surface of the upper portion, and simultaneously, add a light blocking or light scattering function by utilizing the vertical surface of the side surface. Through this, an optical performance and reliability of the light emitting module 100 may be much further improved by simultaneously implementing a light collimation function and a crosstalk prevention function within a single component.

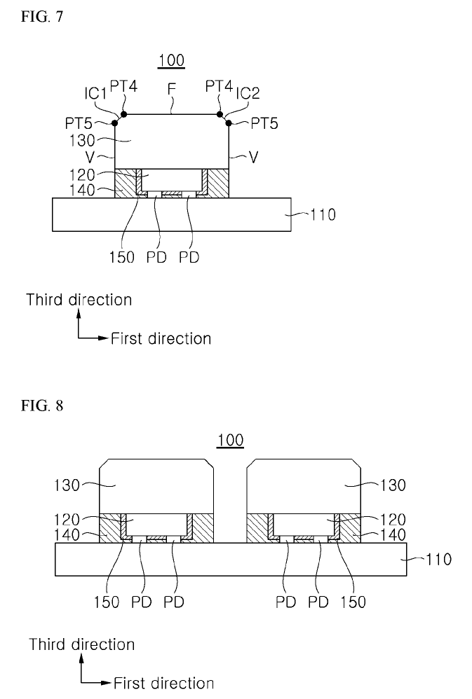

FIG. 7 is a cross-sectional view illustrating a light emitting module 100 according to a seventh embodiment of the present invention. The light emitting module 100 according to the seventh embodiment will be described in detail, focusing on differences from the first through sixth embodiments. In the seventh embodiment, a light exiting surface of the light-transmitting layer 130 may have an angular shape that is a combination of a flat surface and an inclined surface.

In the seventh embodiment, a light emitting device 120 is disposed on the support layer 110, and its side surface may be protected by an insulation layer 150 and a molding layer 140.

An upper surface of the light exiting surface of the light-transmitting layer 130 may be a flat surface F parallel to a first direction and a second direction.

In addition, a side surface of the light exiting surface may include inclined surfaces IC1 and IC2 having a slope. The inclined surfaces IC1 and IC2 may start from a corner PT4 that meets the flat surface F of an upper portion and continue to a corner PT5 that meets a vertical side surface of a lower portion.

The inclined surfaces IC1 and IC2, based on a total vertical height of the light-transmitting layer 130, may be positioned between an upper-lower center line and the flat surface F at an upper end, that is, in an upper half. Among light emitted from the light emitting device 120, light directed toward a center portion may be directly emitted to the outside without loss by going straight with minimal refraction through the flat upper surface F. Meanwhile, light that spreads widely to the side surface of the light exiting surface may meet the inclined surfaces IC1 and IC2 positioned in the upper half. The inclined surfaces IC1 and IC2 act like a surface of a prism, and may refract light directed to the side surface inward, that is, in a front direction (a third direction). By designing a most effective refractive action for light collimation to occur intensively in the upper half of the light-transmitting layer 130, an overall beam divergence angle may be reduced and directivity thereof may be increased, thereby maximizing the light collimation efficiency.

Forming a trapezoidal angular light-transmitting layer 130 structure of FIG. 7 may be easier and more cost-effective than forming a smooth curved shape. In addition, the flat upper surface F may be used for attaching other optical components (e.g., filters, polarizing plates) or an arrangement reference surface in subsequent processes.

FIG. 8 is a cross-sectional view illustrating a light emitting module 100 according to an eighth embodiment of the present invention. The light emitting module 100 according to the eighth embodiment will be described in detail, focusing on differences from the first through seventh embodiments.

The eighth embodiment shows a similar concept to that of the second embodiment of FIG. 2 in that it is an array structure in which a plurality of single light emitting units having a trapezoidal light-transmitting layer 130 are disposed on one support layer 110. FIG. 7 shows only one light emitting unit, whereas FIG. 8 may be an array structure in which two identical light emitting units are disposed in flush along a first direction.

Through this, it is possible to facilitate a manufacturing process in an array process that forms a plurality of light-transmitting layers 130 at a wafer level or panel level at once. A large number of light-transmitting layers 130 may be precisely patterned simultaneously using lithography and etching processes using a single mask, thereby significantly improving overall productivity and price competitiveness.

In addition, each of the light emitting units is physically completely isolated, and a certain separation distance therebetween may exist. Such a separation space may play a role as a minimum barrier for optical isolation between adjacent channels. In particular, since a side surface of each of the light-transmitting layers 130 is clearly defined in a vertical or inclined shape, a propagation path of stray light leaking to the side surface may be predicted and easily controlled. When the above-described modified region is formed on a side surface of an exiting surface of the light-transmitting layer 130, an effect of suppressing crosstalk in the array structure may be maximized.

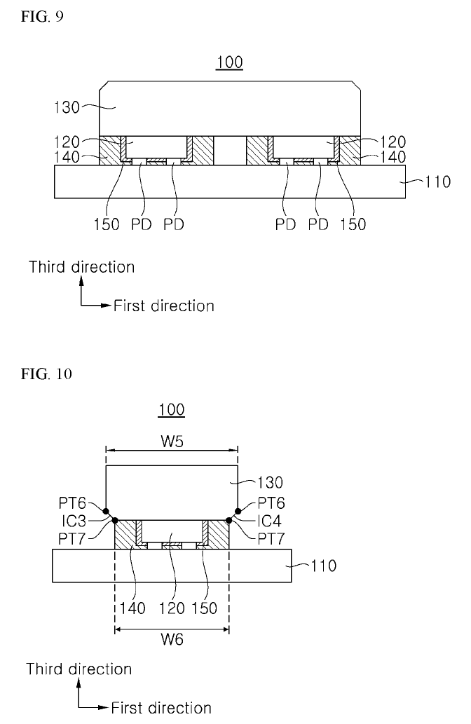

FIG. 9 is a cross-sectional view illustrating a light emitting module 100 according to a ninth embodiment of the present invention. The light emitting module 100 according to the ninth embodiment will be described in detail, focusing on differences from the first through eighth embodiments.

The ninth embodiment shows a similar concept of a monolithic structure in that a light-transmitting layer 130 formed as one single body shares all of a plurality of light emitting devices 120 as in the fourth embodiment of FIG. 4. However, there is a difference in an overall shape of the light-transmitting layer 130.

The plurality of light emitting devices 120 are spaced apart from one another on the support layer 110, and each of the light emitting devices 120 may be protected by an insulation layer 150 and a molding layer 140. Above them, one continuous light-transmitting layer 130 may cover all of two light emitting devices 120.

Through an angular shape of the light-transmitting layer 130, it is possible to further increase a manufacturability, and since there are no physically isolated parts, a mechanical durability against external shock or vibration may be improved.

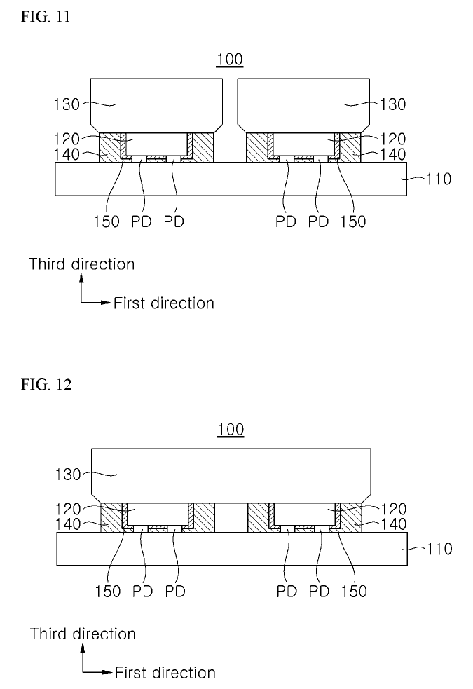

FIG. 10 is a cross-sectional view illustrating a light emitting module 100 according to a tenth embodiment of the present invention. The light emitting module 100 according to the 10th embodiment will be described in detail, focusing on differences from the first through ninth embodiments.

In the tenth embodiment, a light emitting device 120 is disposed on the support layer 110, and its side surface may be protected by an insulation layer 150 and a molding layer 140. A light exiting surface of the light-transmitting layer 130 may have a cross-sectional shape such as an inverted trapezoid or an eave.

In detail, the light exiting surface of the light-transmitting layer 130 may include a flat surface at an upper portion, a vertical side surface there below, and an inwardly inclined surfaces IC3 and IC4 positioned at a lowermost portion. The inclined surfaces IC3 and IC4 may start from a corner PT6 of a side surface and end at a corner PT7 thereunder, and may be positioned between an upper-lower center line and a lower end based on a total vertical height of the light-transmitting layer 130, that is, in a lower half.

In addition, a maximum width W5 of the light-transmitting layer 130 may be formed wider than a maximum width W6 of the molding layer 140 positioned there below. Due to this, a lower end portion of the light-transmitting layer 130 may protrude above the molding layer 140 to form a shape like an eave.

An eave structure in which the lower end portion of the light-transmitting layer 130 covers the molding layer 140 may play a role in blocking and lengthily extending a path through which external moisture or contaminants infiltrate into the light emitting device 120 along a vulnerable interface between the molding layer 140 and the light-transmitting layer 130. This may significantly improve a moisture resistance of the light emitting module 100, thereby securing reliability that allows for long-term stable operation even in a high temperature and high humidity environment.

In addition, a wide lower end portion of the light-transmitting layer 130 may increase a bonding area with the molding layer 140, thereby increasing a bonding strength of an entire structure and improving mechanical stability. Furthermore, resistance to external physical shock or vibration may be increased, thereby enhancing a durability of the light emitting module 100.

Optically, the inclined surfaces IC3 and IC4 formed in the lower half may play a role in controlling a path of stray light emitted at a high angle from the light emitting device 120. For example, light may be designed to be totally internally reflected on the inclined surfaces IC3 and IC4, so that light that has been leaked out to the side surface may be guided back to a useful front direction, or it may be used to adjust a beam profile by scattering it at a specific angle.

FIG. 11 is a cross-sectional view illustrating a light emitting module 100 according to an 11th embodiment of the present invention. The 11th embodiment may be conceptually similar to the eighth embodiment in that it is an array structure in which a plurality of light-transmitting layers 130 of the eave structure of FIG. 10 are disposed on one common support layer 110.

FIG. 12 is a cross-sectional view illustrating a light emitting module 100 according to a 12th embodiment of the present invention. The 12th embodiment may simultaneously improve the manufacturability and structural reliability by combining an integral array structure of a light-transmitting layer 130 and an eave-shaped cross-section.

Since one continuous light-transmitting layer 130 covers entire plurality of light emitting devices 120 at once, and a cross-section of this light-transmitting layer 130 has a shape as that shown in FIG. 10, so that a manufacturing process may be facilitated and environmental resistance may be improved.

Meanwhile, in the embodiments described above, the light-transmitting layer 130 may be a component that is manufactured and attached additionally, but alternatively, it may be a light-transmitting growth substrate used for a growth of the light emitting device 120, for example, a sapphire substrate. That is, the substrate on which semiconductor layers constituting the light emitting device 120 are grown may be used as the light-transmitting layer 130 that performs an optical function. The shape, groove G, inclined surfaces IC1, IC2, and IC3, or others of the light-transmitting layer 130 described above may be formed by processing the growth substrate.

The light emitting module 100 according to the embodiment of the present invention may be applied to various light emitting systems.

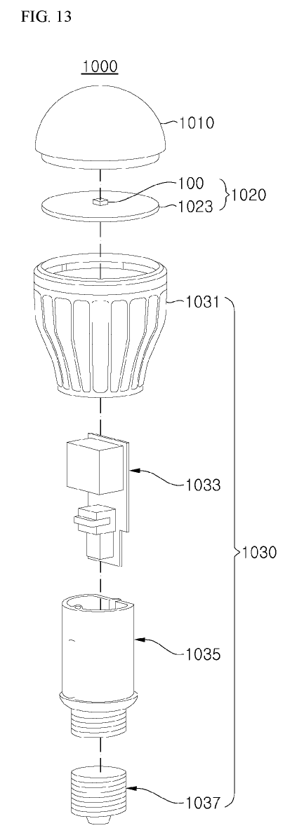

First, FIG. 13 is a light emitting system according to the first embodiment of the present invention, and the light emitting system may be a lighting apparatus 1000 including at least one light emitting module 100 described above.

Referring to FIG. 13, the lighting apparatus 1000 may include a diffusion cover 1010, a light source module 1020, and a body 1030. The body 1030 may accommodate the light source module 1020, and the diffusion cover 1010 may be disposed on the body 1030 so as to cover an upper portion of the light source module 1020.

The body 1030 is not limited as long as it has a form that may accommodate and support the light source module 1020 and supply electrical power to the light source module 1020. For example, as illustrated, the body 1030 may include a body case 1031, a power supply 1033, a power case 1035, and a power connection portion 1037.

The power supply 1033 is accommodated in the power case 1035 and electrically connected to the light source module 1020, and may include at least one IC chip. The IC chip may adjust, convert or control characteristics of the power supplied to the light source module 1020. The power case 1035 may accommodate and support the power supply 1033, and the power supply case 1035 having the power supply 1033 secured therein may be positioned inside the body case 1031. The power connection portion 1037 is disposed at a lower end of the power case 1035, and may be connected to the power case 1035. Accordingly, the power connection portion 1037 is electrically connected to the power supply 1033 inside the power case 1035, and may play a role as a passage through which external power may be supplied to the power supply 1033.

The light source module 1020 may include a substrate 1023 and at least one light emitting module 100 disposed on the substrate 1023. The light source module 1020 may be provided over the body case 1031 and electrically connected to the power supply 1033.

The substrate 1023 is not limited as long as it is a substrate capable of supporting the light emitting module 100, and may be, for example, a printed circuit board including wiring. The substrate 1023 may have a shape corresponding to a securing portion formed at the upper portion of the body case 1031, so as to be stably secured to the body case 1031.

The diffusion cover 1010 is disposed on the light emitting module 100, and may be secured to the body case 1031 to cover the light emitting module 100. The diffusion cover 1010 may be formed of a light transmitting material, and light orientation of the lighting apparatus 1000 may be adjusted through regulation of the shape and optical transmissivity of the diffusion cover 1010. Therefore, the diffusion cover 1010 may be modified to have various shapes depending on usage and applications of the lighting apparatus 1000.

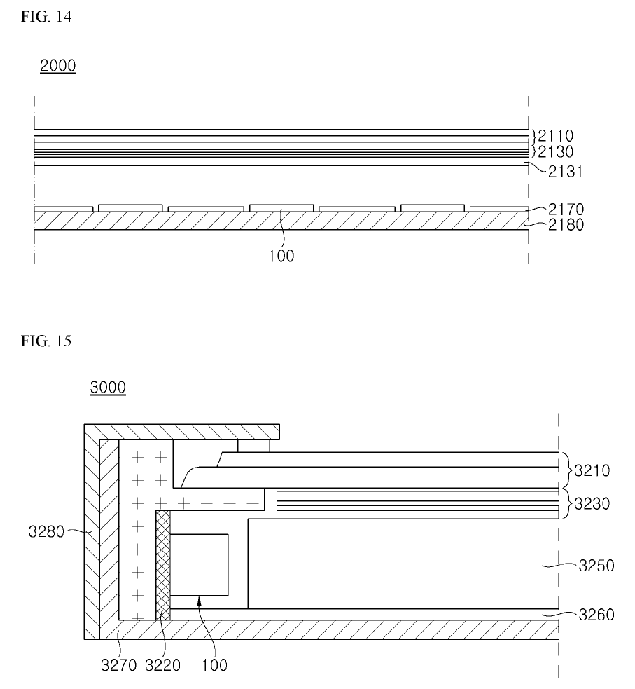

Next, FIG. 14 is a cross-sectional view of a light emitting system according to the second embodiment of the present invention, and the light emitting system may be a display apparatus 2000 including at least one light emitting module 100 described above.

The display apparatus 2000 may include a display panel 2110, a backlight unit that provides light to the display panel 2110, and a panel guide that supports a lower edge of the display panel 2110.

The display panel 2110 is not particularly limited, and may be, for example, a liquid crystal display panel including a liquid crystal layer. A gate driving PCB that supplies a driving signal to a gate line may be further positioned at the edge of the display panel 2110. Herein, the gate drive PCB may not be formed on an additional PCB, but may be formed on a thin film transistor substrate. A pixel of the display panel 2110 may be an LED display implemented by the light emitting module 100 of the present invention. In a case that the display panel 2110 is the LED display, the backlight unit described later may be omitted.

The backlight unit may include a light source module including at least one substrate and a plurality of light emitting modules 100. Moreover, the backlight unit may further include a bottom cover 2180, a reflection sheet 2170, a diffusion plate 2131, and optical sheets 2130.

The bottom cover 2180 may be opened upwards, and may house the substrate, the light emitting module 100, the reflection sheet 2170, the diffusion plate 2131, and the optical sheets 2130. In addition, the bottom cover 2180 may be couped to the panel guide. The substrate may be positioned under the reflection sheet 2170, and may be disposed in a form surrounded by the reflection sheet 2170. However, the inventive concepts are not limited thereto, and in a case that a reflection material is coated on a surface thereof, the substrate may be positioned on the reflection sheet 2170. In addition, the substrate may be formed in a plurality, and arranged in a form flush with one another in which a plurality of substrates are disposed, without being limited thereto, and may be formed as a single substrate.

The light emitting modules 100 may be regularly arranged in a certain pattern on the substrate. In addition, a lens may be disposed on each of the light emitting modules 100, thereby improving a uniformity of light emitted from the light emitting module 100.

The diffusion plate 2131 and the optical sheets 2130 are positioned on the light emitting module 100. Light emitted from the light emitting module 100 may be supplied to the display panel 2110 in a form of a surface light source through the diffusion plate 2131 and the optical sheets 2130.

As such, the light emitting module 100 according to the embodiments of the present invention may be applied to a direct display apparatus 2000 such as that of the present embodiment.

Next, FIG. 15 is a cross-sectional view of a light emitting system according to the third embodiment of the present invention, and the light emitting system may be a display apparatus 3000 including at least one light emitting module 100 described above.

The display apparatus 3000 equipped with a backlight unit may include a display panel 3210 on which an image is displayed, and a backlight unit disposed on a rear surface of the display panel 3210 to irradiate light. Furthermore, the display apparatus 3000 may include a frame that supports the display panel 3210 and accommodates the backlight unit and coves 3240 and 3280 that surround the display panel 3210.

The display panel 3210 is not particularly limited, and may be, for example, a liquid crystal display panel including a liquid crystal layer. A gate driving PCB that supplies a driving signal to a gate line may be further positioned at an edge of the display panel 3210. Herein, the gate drive PCB may not be formed on an additional PCB, but may be formed on a thin film transistor substrate. The display panel 3210 is secured by the covers 3240 and 3280 positioned under and over the display panel 3210, and the cover 3280 positioned under the display panel 3210 may be coupled to the backlight unit.

The backlight unit that provides light to the display panel 3210 includes a lower cover 3270 having a portion of an upper surface opened, a light source module disposed on one inner side of the lower cover 3270 and a light guide plate 3250 positioned in flush with the light source module to convert point light into surface light. In addition, the backlight unit of the present embodiment may further include optical sheets 3230 positioned on the light guide plate 3250 to diffuse and collimate light, and a reflection sheet 3260 disposed under the light guide plate 3250 to reflect light traveling downward of the light guide plate 3250 toward the display panel 3210.

The light source module may include a substrate 3220 and light emitting modules 100 spaced apart at a regular interval on a surface of the substrate 3220. The substrate 3220 is not limited as long as it supports the light emitting module 100 and is electrically connected to the light emitting module 100, and may be, for example, a printed circuit board.

Light emitted from the light source module may be incident on the light guide plate 3250 and supplied to the display panel 3210 through the optical sheets 3230. Through the light guide plate 3250 and the optical sheets 3230, a point light source emitted from the light emitting module 100 may be transformed into a surface light source. As such, the light emitting module 100 according to the embodiments of the present invention may be applied to an edge-type display apparatus 3000 such as that of the present embodiment.

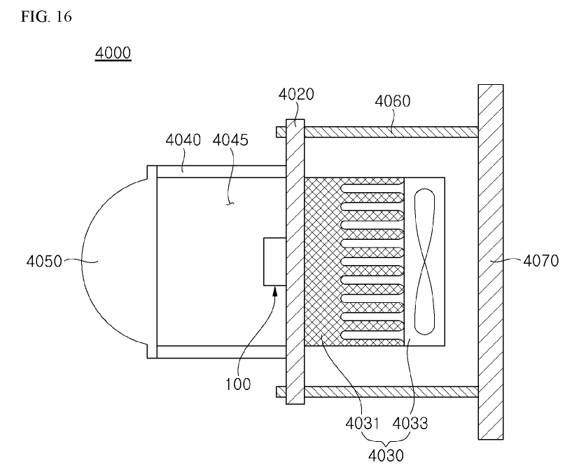

Next, FIG. 16 is a cross-sectional view of a light emitting system according to the fourth embodiment of the present invention, and the light emitting system may be a head lamp 4000 including at least one light emitting module 100 described above.

Referring to FIG. 16, the head lamp 4000 may include a lamp body 4070, a substrate 4020, the light emitting module 100, and a cover lens 4050. Furthermore, the head lamp 4000 may further include a heat dissipation unit 4030, a support rack 4060 and a connection member 4040.

The substrate 4020 may be secured by the support rack 4060 and spaced apart from the lamp body 4070. The substrate 4020 is not limited as long as it is a substrate capable of supporting the light emitting module 100, and may be, for example, a substrate having a conductive pattern such as a printed circuit board. The light emitting module 100 is positioned on the substrate 4020, and may be supported and secured by the substrate 4020. In addition, the light emitting module 100 may be electrically connected to an external power source through the conductive pattern of the substrate 4020.

The cover lens 4050 may be positioned on a path along which light emitted from the light emitting module 100 moves. For example, as illustrated, the cover lens 4050 may be spaced apart from the light emitting module 100 by a connection member 4040, and may be disposed in a direction in which light emitted from the light emitting module 100 is desired to be provided. A viewing angle and/or color of light emitted from the head lamp 4000 to the outside may be adjusted by the cover lens 4050.

Meanwhile, the connection member 4040 may secure the cover lens 4050 to the substrate 4020, and may be disposed to surround the light emitting module 100 to play a role as a light guide that provides a light emitting path 4045. In this case, the connection member 4040 may be formed of a light reflective material or coated therewith. Meanwhile, the heat dissipation unit 4030 may include a heat dissipation fin 4031 and/or a heat dissipation fan 4033, and may dissipate heat generated upon operating the light emitting module 100 to the outside.

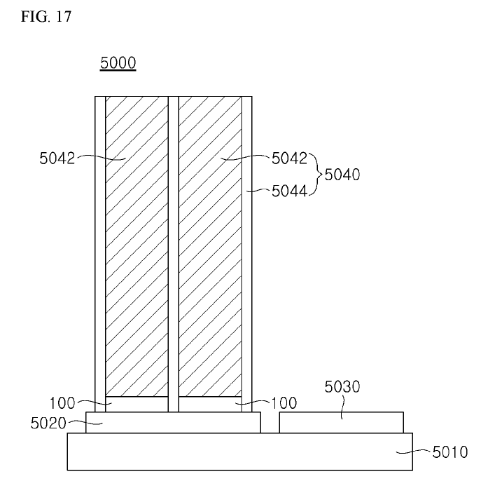

Next, FIG. 17 is a cross-sectional view of a light emitting system according to the fifth embodiment of the present invention, and the light emitting system may be an optical communication interconnector 5000 including at least one light emitting module 100 described above.

The light emitting system 5000 may include a substrate 5010, a frame 5020, a D2D interface 5030 and an optical transmission unit 5040.

The substrate 5010 may be a package substrate that supports an entire system, or a main logic chip itself(e.g., CPU) that performs actual operations.

One or more light emitting modules 100 according to the embodiment of the present invention may be disposed on the substrate 5010. The light emitting module 100 performs a role as a ‘light transmission unit’ within the system, and may include the array of light emitting devices 120as described in the previous embodiments, and the integrated or discrete light-transmitting layer (a lens array, 130) for collimating light emitted from each of the devices.

The light emitting module 100 may be supported by the frame 5020 thereunder. The frame 5020 may mechanically and stably secure the light emitting module 100, and ensure a precise height arrangement with the optical transmission unit 5040 which will be described later.

The D2D interface 5030 may be disposed in flush with the light emitting module 100 on the substrate 5010. The D2D interface 5030 may be an electrical passage connecting the main logic chip corresponding to the substrate 5010 and the light emitting module 100 for transmitting and receiving optical signals. That is, a high-speed electrical data signal generated from the main logic chip may be transmitted to the light emitting module 100 through the D2D interface 5030.

The optical transmission unit 5040 may be arranged and combined over the light emitting module 100. The optical transmission unit 5040 may include a fiber bundle in which numerous discrete optical fibers 5042 are bundled and a housing (Ferrule, 5044) that secures the fiber bundle in a grid structure. Through the housing 5044, a core of each of the optical fibers 5042 may be arranged to correspond exactly one-to-one to each micro light emitting device within the light emitting module 100.

The light emitting module 100 according to the embodiment of the present invention may be applied to various lightings, displays, BLUs, vehicle lighting apparatuses, or others, in addition to the light emitting system described above.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100: Light emitting module

110: Support layer

120: Light emitting device

130: Light-transmitting layer

140: Molding layer

150: Insulation layer

160: Connection layer

1000, 2000, 3000, 4000, 5000: Light emitting system

What is claimed is:

1. A light emitting module, comprising:
a support layer;
a light emitting device disposed on the support layer; and
a light-transmitting layer disposed on an upper surface of the light emitting device,
wherein a point where an absolute value of a tangent slope of a light exiting surface of the light-transmitting layer is 1 is positioned between an upper-lower center line of the light-transmitting layer and an upper end of the light-transmitting layer.

2. The light emitting module of claim 1,
wherein a vertical center axis of the light-transmitting layer is spaced apart from a vertical center axis of the light emitting device.

3. The light emitting module of claim 1,
wherein a vertical length from the upper surface of the light emitting device to the upper end of the light-transmitting layer is longer than a vertical length of the light emitting device.

4. The light emitting module of claim 1, further comprising:
a plurality of light emitting devices including the light emitting device disposed on the support layer; and
a plurality of light-transmitting layers, each of which is provided on an upper surface of a respective one of the plurality of light emitting devices.

5. The light emitting module of claim 4,
wherein a center-to-center distance between two adjacent light-transmitting layers of the plurality of light-transmitting layers is longer than a width of the light emitting device.

6. The light emitting module of claim 4,
wherein a separation distance between two adjacent light-transmitting layers of the plurality of light-transmitting layers is shorter than a separation distance between two adjacent light emitting devices of the plurality of light emitting devices.

7. The light emitting module of claim 4,
wherein a separation distance between two adjacent light-transmitting layers of the plurality of light-transmitting layers is shorter than a width of the light emitting device.

8. The light emitting module of claim 4,
wherein a separation distance between two adjacent light emitting devices of the plurality of light emitting devices is longer than a width of the light emitting device.

9. The light emitting module of claim 4, further comprising:
a connection layer connecting two adjacent light-transmitting layers of the plurality of light-transmitting layers.

10. The light emitting module of claim 9,
wherein a concave groove is formed at a lower portion of the connection layer.

11. The light emitting module of claim 1, further comprising:
a plurality of light emitting devices including the light emitting device disposed on the support layer,
wherein the plurality of light emitting devices share the light-transmitting layer.

12. The light emitting module of claim 1,
wherein the light exiting surface of the light-transmitting layer is a convex surface.

13. The light emitting module of claim 1,
wherein the light exiting surface of the light-transmitting layer further includes a vertical surface on a side surface.

14. The light emitting module of claim 1,
wherein the light exiting surface of the light-transmitting layer has a modified region formed on a side surface.

15. A light emitting module, comprising:
a support layer;
a light emitting device disposed on the support layer; and
a light-transmitting layer disposed on an upper surface of the light emitting device, wherein:
a light exiting surface of the light-transmitting layer includes an inclined surface having a slope, and
the inclined surface is positioned between an upper-lower center line of the light-transmitting layer and an upper end of the light-transmitting layer.

16. The light emitting module of claim 15,
wherein an upper surface of the light exiting surface is a flat surface.

17. The light emitting module of claim 15, further comprising:
a molding layer disposed on a side surface of the light emitting device.

18. The light emitting module of claim 15, further comprising:
a plurality of light emitting devices including the light emitting device disposed on the support layer,
wherein the plurality of light emitting devices share the light-transmitting layer.

19. A light emitting module, comprising:
a support layer;
a light emitting device disposed on the support layer; and
a light-transmitting layer disposed on an upper surface of the light emitting device, wherein:
a light exiting surface of the light-transmitting layer includes an inclined surface having a slope, and
the inclined surface is positioned between an upper-lower center line of the light-transmitting layer and a lower end of the light-transmitting layer.

20. The light emitting module of claim 19, further comprising:
a molding layer disposed on a side surface of the light emitting device,
wherein a maximum width of the light-transmitting layer is wider than a maximum width of the molding layer.
